(19) United States
(12) Patent Application Publication
(10) Pub. No.: US 2026/0125822 A1
(43) Pub. Date: May 7, 2026

(54) DOPED SUBSTANTIALLY SINGLE-PHASE RARE EARTH OXIDE-ZIRCONIA MATERIALS AND METHODS OF MAKING THE SAME

(71) Applicant: CoorsTek, Inc., Golden, CO (US)

(72) Inventors: Steven Landin, Conifer, CO (US); David Henry Hook, Lakewood, CO (US)

(21) Appl. No.: 19/435,475

(22) Filed: Dec. 29, 2025

Related U.S. Application Data
(63) Continuation of application No. PCT/US2024/035459, filed on Jun. 25, 2024.
(60) Provisional application No. 63/525,069, filed on Jul. 5, 2023.

(51) Int. Cl. C30B 29/22; B22F 1/12; B22F 3/15; C30B 28/02

(52) U.S. Cl. CPC C30B 29/22; B22F 1/12; C30B 28/02; B22F 3/15; B22F 2302/25

(57) ABSTRACT

New substantially single-phase polycrystalline materials are disclosed. The new substantially single-phase polycrystalline materials generally include from 0.01-20 mol. % zirconia, at least 80 mol. % of one or more rare earth oxides (REO), and 40 to 7000 ppm aluminum by weight, wherein the substantially single-phase polycrystalline material comprises at least 95 wt. % of a solid-solution of REO-zirconia as measured by x-ray diffraction. The new substantially single-phase polycrystalline materials may realize a high density, such as a density of at least 95% of theoretical density, or higher. The new substantially single-phase polycrystalline materials may be in the form of a semiconductor component, including those suited for use in a plasma chamber environment.

### CROSS-REFERENCE TO RELATED APPLICATION

This patent application is a continuation of International Patent Application No. PCT/US2024/035459, entitled “DOPED SUBSTANTIALLY SINGLE-PHASE RARE EARTH OXIDE-ZIRCONIA MATERIALS AND METHODS OF MAKING THE SAME,” filed Jun. 25, 2024, which claims priority to U.S. Provisional Patent Application No. 63/525,069, entitled, “DOPED SUBSTANTIALLY SINGLE-PHASE YTTRIA-ZIRCONIA MATERIALS AND METHODS OF MAKING THE SAME,” filed on Jul. 5, 2023. Each of the above-identified patent applications are hereby incorporated by reference in their entirety.

### BACKGROUND

Corrosion and erosion resistance are critical properties for apparatus components and liners used in semiconductor processing chambers, where corrosive environments are present. Examples of corrosive plasma environments include plasmas used for cleaning of processing apparatus and plasmas used to etch semiconductor substrates. Yttrium oxide ceramics may realize plasma resistance properties, but yttrium oxide generally exhibits weak mechanical properties that limits its applications for general use in semiconductor processing components.

### SUMMARY OF THE DISCLOSURE

Broadly, the present patent application relates to new substantially single-phase polycrystalline materials having improved properties. In one approach, the new substantially single-phase polycrystalline materials generally include: (A) one or more rare earth oxide (“REO”) materials and (B) zirconia (ZrO₂). In one embodiment, the new materials may comprise a solid solution of REO-zirconia, wherein zirconium periodically substitutes for the REO material on the REO lattice. The new substantially single-phase polycrystalline materials generally include at least 80 mol. % of the one or more REO materials and from 0.01 to 20 mol. % zirconia. The new single-phase polycrystalline materials also generally include from 40 to 7000 ppm by weight of aluminum. In one embodiment, the one or more REO materials comprise one or more oxides of the Lanthanide series of elements. In one embodiment, the one or more REO materials at least include yttrium oxide (yttria). In another embodiment, the one or more REO materials at least include ytterbium oxide (ytterbia). In another embodiment, the one or more REO materials at least include both yttrium oxide and ytterbium oxide. Other combinations of REO materials may be used. In one embodiment, at least one rare earth sesquioxide having the formula RE₂O₃ (e.g., Y₂O₃, Yb₂O₃, Gd₂O₃, Er₂O₃, and Dy₂O₃, among others) is used as a REO material. For purposes of illustration, reference is now made to yttria-zirconia materials. It is to be appreciated that the yttria-zirconia disclosures herein generally apply to other REO-zirconia materials.

As noted above, the new substantially single-phase polycrystalline materials may comprise (or consist of, or consist essentially of) a solid solution of yttria-zirconia, wherein zirconium periodically substitutes for yttrium on the yttria cubic lattice. To facilitate the substantially single-phase solid solution, the new single-phase polycrystalline materials generally include from 0.01 to 20 mol. % zirconia and at least 80 mol. % yttria. The new single-phase polycrystalline materials also generally include from 40 to 7000 ppm by weight of aluminum. The new substantially single-phase polycrystalline materials may realize a high density, such as a density of at least 95% of theoretical density. The new substantially single-phase polycrystalline materials may realize a fine grain structure (e.g., an average grain size of not greater than 7 micrometers). The new substantially single-phase polycrystalline materials may realize a uniform grain structure (e.g., less than 10% of the grains are more than twice the average grain size). The new substantially single-phase polycrystalline materials may be resistant to erosion by halogen plasmas. The new substantially single-phase polycrystalline materials may be in the form of a monolithic (bulk) material, such as in the form of a shaped component. The shaped component may be suited for use, for instance, as a semiconductor component, including semiconductor components suited for use in a plasma processing chamber. Additional details are provided below.

### i. Substantially Single-Phase Material Compositions and Microstructures

As noted above, the new substantially single-phase polycrystalline materials may comprise (and may consist of, or consist essentially of) (i) a yttria-zirconia solid solution phase and (ii) from 40 to 7000 ppm of aluminum, which aluminum may also be present within the solid solution phase and/or may be present in another phase (e.g., the YAM phase (Y₄Al₂O₉)).

As used herein, “substantially single-phase polycrystalline materials” means polycrystalline materials having at least 95 wt. % of a solid solution of yttria-zirconia (or REO-zirconia, if other REOs are used) as determined using x-ray diffraction (XRD). In other words, up to 5 wt. % of phases other than the yttria-zirconia solid solution phase may be present. These other phases may include, for instance, the YAM phase (Y₄Al₂O₉). In one embodiment, a substantially single-phase polycrystalline material includes at least 96 wt. % of the yttria-zirconia solid solution phase. In another embodiment, a substantially single-phase polycrystalline material includes at least 97 wt. % of the yttria-zirconia solid solution phase. In yet another embodiment, a substantially single-phase polycrystalline material includes at least 98 wt. % of the yttria-zirconia solid solution phase. In another embodiment, a substantially single-phase polycrystalline material includes at least 98.2 wt. % of the yttria-zirconia solid solution phase. In yet another embodiment, a substantially single-phase polycrystalline material includes at least 98.4 wt. % of the yttria-zirconia solid solution phase. In another embodiment, a substantially single-phase polycrystalline material includes at least 98.6 wt. % of the yttria-zirconia solid solution phase. In yet another embodiment, a substantially single-phase polycrystalline material includes at least 98.8 wt. % of the yttria-zirconia solid solution phase. In another embodiment, a substantially single-phase polycrystalline material includes at least 99.0 wt. % of the yttria-zirconia solid solution phase. In yet another embodiment, a substantially single-phase polycrystalline material includes at least 99.2 wt. % of the yttria-zirconia solid solution phase. In another embodiment, a substantially single-phase polycrystalline material includes at least 99.4 wt. % of the yttria-zirconia solid solution phase. In yet another embodiment, a substantially single-phase polycrystalline material includes at least 99.5 wt. % of the yttria-zirconia solid solution phase. In another embodiment, a substantially single-phase polycrystalline material includes at least 99.6 wt. % of the yttria-zirconia solid solution phase. In yet another embodiment, a substantially single-phase polycrystalline material includes at least 99.7 wt. % of the yttria-zirconia solid solution phase. In another embodiment, a substantially single-phase polycrystalline material includes at least 99.8 wt. % of the yttria-zirconia solid solution phase. In yet another embodiment, a substantially single-phase polycrystalline material includes at least 99.9 wt. % of the yttria-zirconia solid solution phase. In another embodiment, a substantially single-phase polycrystalline material includes 100 wt. % of the yttria-zirconia solid solution phase. As may be appreciated, because XRD is used to quantify the amount of yttria-zirconia solid solution phase and other phase(s) of the material, a material may include very small amounts of other phase(s), but those phases may not be detected by XRD. Thus, in some instances, the substantially single-phase polycrystalline material may be considered a 100% solid solution of yttria-zirconia, even though some other phases may be present in undetectable quantities. The above disclosures surrounding substantially single-phase polycrystalline materials applies to other REO-zirconia materials, as described herein below.

As noted above, the new substantially single-phase polycrystalline materials generally include from 0.01 to 20 mol. % zirconia. In one embodiment, a substantially single-phase polycrystalline material includes at least 0.05 mol. % zirconia. In another embodiment, a substantially single-phase polycrystalline material includes at least 0.10 mol. % zirconia. In yet another embodiment, a substantially single-phase polycrystalline material includes at least 0.25 mol. % zirconia. In another embodiment, a substantially single-phase polycrystalline material includes at least 0.50 mol. % zirconia. In yet another embodiment, a substantially single-phase polycrystalline material includes at least 0.75 mol. % zirconia. In another embodiment, a substantially single-phase polycrystalline material includes at least 1.0 mol. % zirconia. In yet another embodiment, a substantially single-phase polycrystalline material includes at least 1.5 mol. % zirconia. In another embodiment, a substantially single-phase polycrystalline material includes at least 2.0 mol. % zirconia. In yet another embodiment, a substantially single-phase polycrystalline material includes at least 2.5 mol. % zirconia. In another embodiment, a substantially single-phase polycrystalline material includes at least 3.0 mol. % zirconia. In yet another embodiment, a substantially single-phase polycrystalline material includes at least 3.5 mol. % zirconia. In another embodiment, a substantially single-phase polycrystalline material includes at least 4.0 mol. % zirconia. In yet another embodiment, a substantially single-phase polycrystalline material includes at least 4.5 mol. % zirconia. In another embodiment, a substantially single-phase polycrystalline material includes at least 5.0 mol. % zirconia. In yet another embodiment, a substantially single-phase polycrystalline material includes at least 5.5 mol. % zirconia. In another embodiment, a substantially single-phase polycrystalline material includes at least 6.0 mol. % zirconia. In yet another embodiment, a substantially single-phase polycrystalline material includes at least 6.5 mol. % zirconia. In another embodiment, a substantially single-phase polycrystalline material includes at least 7.0 mol. % zirconia. In yet another embodiment, a substantially single-phase polycrystalline material includes at least 7.5 mol. % zirconia. In another embodiment, a substantially single-phase polycrystalline material includes at least 8.0 mol. % zirconia. In yet another embodiment, a substantially single-phase polycrystalline material includes at least 8.5 mol. % zirconia. In another embodiment, a substantially single-phase polycrystalline material includes at least 9.0 mol. % zirconia. In yet another embodiment, a substantially single-phase polycrystalline material includes at least 9.5 mol. % zirconia. In another embodiment, a substantially single-phase polycrystalline material includes at least 10.0 mol. % zirconia.

In one embodiment, a substantially single-phase polycrystalline material includes not greater than 19.5 mol. % zirconia. In another embodiment, a substantially single-phase polycrystalline material includes not greater than 19.0 mol. % zirconia. In yet another embodiment, a substantially single-phase polycrystalline material includes not greater than 18.5 mol. % zirconia. In another embodiment, a substantially single-phase polycrystalline material includes not greater than 18.0 mol. % zirconia. In yet another embodiment, a substantially single-phase polycrystalline material includes not greater than 17.5 mol. % zirconia. In another embodiment, a substantially single-phase polycrystalline material includes not greater than 17.0 mol. % zirconia. In yet another embodiment, a substantially single-phase polycrystalline material includes not greater than 16.5 mol. % zirconia. In another embodiment, a substantially single-phase polycrystalline material includes not greater than 16.0 mol. % zirconia. In yet another embodiment, a substantially single-phase polycrystalline material includes not greater than 15.5 mol. % zirconia. In another embodiment, a substantially single-phase polycrystalline material includes not greater than 15.0 mol. % zirconia. In yet another embodiment, a substantially single-phase polycrystalline material includes not greater than 14.5 mol. % zirconia. In another embodiment, a substantially single-phase polycrystalline material includes not greater than 14.0 mol. % zirconia. In yet another embodiment, a substantially single-phase polycrystalline material includes not greater than 13.5 mol. % zirconia. In another embodiment, a substantially single-phase polycrystalline material includes not greater than 13.0 mol. % zirconia. In yet another embodiment, a substantially single-phase polycrystalline material includes not greater than 12.5 mol. % zirconia. In another embodiment, a substantially single-phase polycrystalline material includes not greater than 12.0 mol. % zirconia. In yet another embodiment, a substantially single-phase polycrystalline material includes not greater than 11.5 mol. % zirconia. In another embodiment, a substantially single-phase polycrystalline material includes not greater than 11.0 mol. % zirconia. In yet another embodiment, a substantially single-phase polycrystalline material includes not greater than 10.5 mol. % zirconia. In another embodiment, a substantially single-phase polycrystalline material includes not greater than 10.0 mol. % zirconia.

As noted above, the new substantially single-phase polycrystalline materials generally include at least 80 mol. % yttria (or other REO materials, as described herein below). In one embodiment, a substantially single-phase polycrystalline material includes at least 81 mol. % yttria. In another embodiment, a substantially single-phase polycrystalline material includes at least 82 mol. % yttria. In yet another embodiment, a substantially single-phase polycrystalline material includes at least 83 mol. % yttria. In another embodiment, a substantially single-phase polycrystalline material includes at least 84 mol. % yttria. In yet another embodiment, a substantially single-phase polycrystalline material includes at least 85 mol. % yttria. In another embodiment, a substantially single-phase polycrystalline material includes at least 86 mol. % yttria. In yet another embodiment, a substantially single-phase polycrystalline material includes at least 87 mol. % yttria. In another embodiment, a substantially single-phase polycrystalline material includes at least 88 mol. % yttria. In yet another embodiment, a substantially single-phase polycrystalline material includes at least 89 mol. % yttria. In another embodiment, a substantially single-phase polycrystalline material includes at least 90 mol. % yttria. In yet another embodiment, a substantially single-phase polycrystalline material includes at least 91 mol. % yttria. In another embodiment, a substantially single-phase polycrystalline material includes at least 92 mol. % yttria. In yet another embodiment, a substantially single-phase polycrystalline material includes at least 93 mol. % yttria. In another embodiment, a substantially single-phase polycrystalline material includes at least 94 mol. % yttria. In yet another embodiment, a substantially single-phase polycrystalline material includes at least 95 mol. % yttria. In another embodiment, a substantially single-phase polycrystalline material includes at least 96 mol. % yttria. In yet another embodiment, a substantially single-phase polycrystalline material includes at least 97 mol. % yttria. In another embodiment, a substantially single-phase polycrystalline material includes at least 98 mol. % yttria. In yet another embodiment, a substantially single-phase polycrystalline material includes at least 99 mol. % yttria. In another embodiment, a substantially single-phase polycrystalline material includes at least 99.5 mol. % yttria. In yet another embodiment, a substantially single-phase polycrystalline material includes at least 99.75 mol. % yttria. The above disclosures surrounding yttria content apply to other REO-zirconia materials, as described herein below.

As noted above, the new substantially single-phase polycrystalline materials generally include from 40 to 7000 ppm by weight of aluminum. The amount of aluminum may be determined using, for instance, inductively coupled plasma (ICP) mass spectrometry techniques. In one embodiment, a substantially single-phase polycrystalline material includes at least 100 ppm (by weight) aluminum. In another embodiment, a substantially single-phase polycrystalline material includes at least 200 ppm (by weight) aluminum. In yet another embodiment, a substantially single-phase polycrystalline material includes at least 250 ppm (by weight) aluminum. In another embodiment, a substantially single-phase polycrystalline material includes at least 300 ppm (by weight) aluminum. In yet another embodiment, a substantially single-phase polycrystalline material includes at least 350 ppm (by weight) aluminum. In another embodiment, a substantially single-phase polycrystalline material includes at least 400 ppm (by weight) aluminum. In yet another embodiment, a substantially single-phase polycrystalline material includes at least 450 ppm (by weight) aluminum. In another embodiment, a substantially single-phase polycrystalline material includes at least 500 ppm (by weight) aluminum. In yet another embodiment, a substantially single-phase polycrystalline material includes at least 550 ppm (by weight) aluminum. In another embodiment, a substantially single-phase polycrystalline material includes at least 600 ppm (by weight) aluminum. In yet another embodiment, a substantially single-phase polycrystalline material includes at least 650 ppm (by weight) aluminum. In another embodiment, a substantially single-phase polycrystalline material includes at least 700 ppm (by weight) aluminum. In yet another embodiment, a substantially single-phase polycrystalline material includes at least 750 ppm (by weight) aluminum. In another embodiment, a substantially single-phase polycrystalline material includes at least 800 ppm (by weight) aluminum. In yet another embodiment, a substantially single-phase polycrystalline material includes at least 850 ppm (by weight) aluminum. In another embodiment, a substantially single-phase polycrystalline material includes at least 900 ppm (by weight) aluminum. In yet another embodiment, a substantially single-phase polycrystalline material includes at least 1000 ppm (by weight) aluminum. In another embodiment, a substantially single-phase polycrystalline material includes at least 1100 ppm (by weight) aluminum. In yet another embodiment, a substantially single-phase polycrystalline material includes at least 1200 ppm (by weight) aluminum. In another embodiment, a substantially single-phase polycrystalline material includes at least 1300 ppm (by weight) aluminum. In yet another embodiment, a substantially single-phase polycrystalline material includes at least 1400 ppm (by weight) aluminum. In another embodiment, a substantially single-phase polycrystalline material includes at least 1500 ppm (by weight) aluminum.

In one embodiment, a substantially single-phase polycrystalline material includes not greater than 6000 ppm (by weight) aluminum. In another embodiment, a substantially single-phase polycrystalline material includes not greater than 5000 ppm (by weight) aluminum. In yet another embodiment, a substantially single-phase polycrystalline material includes not greater than 4500 ppm (by weight) aluminum. In another embodiment, a substantially single-phase polycrystalline material includes not greater than 4000 ppm (by weight) aluminum. In yet another embodiment, a substantially single-phase polycrystalline material includes not greater than 3500 ppm (by weight) aluminum. In another embodiment, a substantially single-phase polycrystalline material includes not greater than 3000 ppm (by weight) aluminum. In yet another embodiment, a substantially single-phase polycrystalline material includes not greater than 2500 ppm (by weight) aluminum. In another embodiment, a substantially single-phase polycrystalline material includes not greater than 2400 ppm (by weight) aluminum. In yet another embodiment, a substantially single-phase polycrystalline material includes not greater than 2300 ppm (by weight) aluminum. In another embodiment, a substantially single-phase polycrystalline material includes not greater than 2200 ppm (by weight) aluminum. In yet another embodiment, a substantially single-phase polycrystalline material includes not greater than 2100 ppm (by weight) aluminum. In another embodiment, a substantially single-phase polycrystalline material includes not greater than 2000 ppm (by weight) aluminum. In yet another embodiment, a substantially single-phase polycrystalline material includes not greater than 1900 ppm (by weight) aluminum. In another embodiment, a substantially single-phase polycrystalline material includes not greater than 1800 ppm (by weight) aluminum. In yet another embodiment, a substantially single-phase polycrystalline material includes not greater than 1700 ppm (by weight) aluminum. In another embodiment, a substantially single-phase polycrystalline material includes not greater than 1600 ppm (by weight) aluminum. In yet another embodiment, a substantially single-phase polycrystalline material includes not greater than 1500 ppm (by weight) aluminum.

As noted above, the new substantially single-phase polycrystalline materials may realize a fine grain structure. In one embodiment, a substantially single-phase polycrystalline material realizes an average grain size of not greater than 7 micrometers. In another embodiment, a substantially single-phase polycrystalline material realizes an average grain size of not greater than 6 micrometers. In yet another embodiment, a substantially single-phase polycrystalline material realizes an average grain size of not greater than 5 micrometers. In another embodiment, a substantially single-phase polycrystalline material realizes an average grain size of not greater than 4 micrometers. In yet another embodiment, a substantially single-phase polycrystalline material realizes an average grain size of not greater than 3.5 micrometers. In another embodiment, a substantially single-phase polycrystalline material realizes an average grain size of not greater than 3 micrometers. In yet another embodiment, a substantially single-phase polycrystalline material realizes an average grain size of not greater than 2.5 micrometers. In another embodiment, a substantially single-phase polycrystalline material realizes an average grain size of not greater than 2 micrometers. In yet another embodiment, a substantially single-phase polycrystalline material realizes an average grain size of not greater than 1.5 micrometers. In another embodiment, a substantially single-phase polycrystalline material realizes an average grain size of not greater than 1 micrometers. In yet another embodiment, a substantially single-phase polycrystalline material realizes an average grain size of not greater than 0.75 micrometers. In another embodiment, a substantially single-phase polycrystalline material realizes an average grain size of not greater than 0.5 micrometers. In one embodiment, a substantially single-phase polycrystalline material realizes an average grain size of at least 0.1 micrometers.

The new substantially single-phase polycrystalline materials may realize a uniform grain size. In one embodiment, the standard deviation of the grain size (GSσ) is not greater than twice the average grain size (GSₐᵥₑ), i.e., GSσ≤2GSₐᵥₑ. In another embodiment, the standard deviation of the grain size (GSσ) is not greater than 150% of the average grain size (GSₐᵥₑ), i.e., GSσ≤1.5GSₐᵥₑ. In yet another embodiment, the standard deviation of the grain size (GSσ) is not greater than 100% of the average grain size (GSₐᵥₑ), i.e., GSσ≤GSₐᵥₑ. In another embodiment, the standard deviation of the grain size (GSσ) is not greater than 80% of the average grain size (GSₐᵥₑ), i.e., GSσ≤0.8GSₐᵥₑ. In yet another embodiment, the standard deviation of the grain size (GSσ) is not greater than 60% of the average grain size (GSₐᵥₑ), i.e., GSσ≤0.6GSₐᵥₑ. In another embodiment, the standard deviation of the grain size (GSσ) is not greater than 50% of the average grain size (GSₐᵥₑ), i.e., GSσ≤0.5GSₐᵥₑ. In yet another embodiment, the standard deviation of the grain size (GSσ) is not greater than 40% of the average grain size (GSₐᵥₑ), i.e., GSσ≤0.4GSₐᵥₑ. In another embodiment, the standard deviation of the grain size (GSσ) is not greater than 30% of the average grain size (GSₐᵥₑ), i.e., GSσ≤0.3GSₐᵥₑ. In yet another embodiment, the standard deviation of the grain size (GSσ) is not greater than 20% of the average grain size (GSₐᵥₑ), i.e., GSσ≤0.2GSₐᵥₑ.

In one embodiment, a new substantially single-phase polycrystalline material realizes a maximum grain size (GSₘₐₓ) that is not more than twenty times larger than the average grain size (GSₐᵥₑ), i.e., GSₘₐₓ≤20GSₐᵥₑ. In another embodiment, a substantially single-phase polycrystalline material realizes a maximum grain size (GSₘₐₓ) that is not more than 15 times larger than the average grain size (GSₐᵥₑ), i.e., GSₘₐₓ≤15GSₐᵥₑ. In yet another embodiment, a substantially single-phase polycrystalline material realizes a maximum grain size (GSₘₐₓ) that is not more than 12 times larger than the average grain size (GSₐᵥₑ), i.e., GSₘₐₓ≤12GSₐᵥₑ. In another embodiment, a substantially single-phase polycrystalline material realizes a maximum grain size (GSₘₐₓ) that is not more than 10 times larger than the average grain size (GSₐᵥₑ), i.e., GSₘₐₓ≤10GSₐᵥₑ. In yet another embodiment, a substantially single-phase polycrystalline material realizes a maximum grain size (GSₘₐₓ) that is not more than 8 times larger than the average grain size (GSₐᵥₑ), i.e., GSₘₐₓ≤8GSₐᵥₑ. In another embodiment, a substantially single-phase polycrystalline material realizes a maximum grain size (GSₘₐₓ) that is not more than 7 times larger than the average grain size (GSₐᵥₑ), i.e., GSₘₐₓ≤7GSₐᵥₑ. In yet another embodiment, a substantially single-phase polycrystalline material realizes a maximum grain size (GSₘₐₓ) that is not more than 6 times larger than the average grain size (GSₐᵥₑ), i.e., GSₘₐₓ≤6GSₐᵥₑ. In another embodiment, a substantially single-phase polycrystalline material realizes a maximum grain size (GSₘₐₓ) that is not more than 5 times larger than the average grain size (GSₐᵥₑ), i.e., GSₘₐₓ≤5GSₐᵥₑ. In yet another embodiment, a substantially single-phase polycrystalline material realizes a maximum grain size (GSₘₐₓ) that is not more than 4 times larger than the average grain size (GSₐᵥₑ), i.e., GSₘₐₓ≤4GSₐᵥₑ.

### ii. Methods of Manufacture

The new substantially single-phase polycrystalline materials may be produced in a variety of manners, including via various powder processing, pressing, and sintering techniques. In one embodiment, and referring now to FIG. 1, a method (10) comprises producing a green body (100) and then sintering the green body (200) at a sintering temperature, thereby forming a sintered component. The green body generally comprises 0.01-20 mol. % zirconia, at least 80 mol. % yttria (or other REOs), and from 40 to 7000 ppm of aluminum. The sintering temperature may be, for instance, one or more temperatures within the range of from 1200° C. to 1800° C. The sintered component is generally substantially single-phase, realizing at least 95 wt. % of a solid-solution of yttria-zirconia (or REO-zirconia) as measured by x-ray diffraction. The sintered component generally realizes a density of at least 95% of theoretical. In one embodiment, the sintered component is a bulk or monolithic substantially single-phase polycrystalline component. The above disclosures surrounding production of substantially single-phase polycrystalline materials applies to other REO-zirconia materials, as described herein below.

As it relates to the producing the green body step (100), a powder comprising the yttria (or other REOs), zirconia, and aluminum may be formulated to achieve the desired composition. In one embodiment, the formulating step comprises blending a yttria powder (or other REOs) and a zirconia powder, thereby producing a powder blend. In one embodiment, the formulating step comprising contacting the yttria-zirconia powder blend (or REO-zirconia powder blend) with a liquid phase material comprising aluminum. In one embodiment, the liquid phase material is an aqueous aluminum-containing solution. In one embodiment, the aqueous aluminum-containing solution is an aluminum nitrate solution. In another embodiment, the formulating comprises contacting the yttria-zirconia powder blend (or REO-zirconia powder blend) with a solid phase material comprising aluminum. In one embodiment, the solid phase material comprises boehmite. In another embodiment, the solid phase material comprises aluminum-containing milling media, and the formulating step comprises milling the yttria-zirconia powder blend (or REO-zirconia powder blend) with the aluminum-containing milling media, thereby effecting mass transfer of at least some aluminum to the powder blend. In one embodiment, the aluminum-containing milling media comprises alpha alumina. In another approach, the formulating step comprises adding aluminum to at least one of a yttria powder (or other REO powder) and a zirconia powder to achieve the appropriate aluminum content (from 40 to 7000 ppm aluminum), and then blending the yttria powder (or other REO powder) with the zirconia powder. The above disclosures surrounding production of substantially single-phase polycrystalline materials applies to other REO-zirconia materials, as described herein below.

As it relates to the sintering the green body step (200), the sintering may be conducted in any suitable fashion. In one embodiment, the sintering comprises pressureless (ambient pressure) sintering. In another embodiment, the sintering comprises applying pressure during sintering (e.g., hot press sintering; hot isostatic press sintering). The sintering atmosphere may be any suitable gaseous environment. In one embodiment, the sintering comprises sintering in air. In another embodiment, the sintering comprises sintering in a non-oxygen atmosphere (e.g., a hydrogen atmosphere). In another embodiment, the sintering comprises sintering in an inert atmosphere (e.g., an argon atmosphere).

As noted above, the sintering temperature may be, for instance, one or more temperatures within the range of from 1200° C. to 1800° C. In one embodiment, the sintering temperature is not greater than 1750° C. In another embodiment, the sintering temperature is not greater than 1700° C. In yet another embodiment, the sintering temperature is not greater than 1680° C. In another embodiment, the sintering temperature is not greater than 1660° C. In yet another embodiment, the sintering temperature is not greater than 1640° C. In another embodiment, the sintering temperature is not greater than 1620° C. In yet another embodiment, the sintering temperature is not greater than 1600° C.

### iii. Properties

As noted above, the new substantially single-phase polycrystalline materials may realize improved density. In one embodiment, a substantially single-phase polycrystalline material realizes a density of at least 95% of its theoretical density. In another embodiment, a substantially single-phase polycrystalline material realizes a density of at least 96% of its theoretical density. In yet another embodiment, a substantially single-phase polycrystalline material realizes a density of at least 96.5% of its theoretical density. In another embodiment, a substantially single-phase polycrystalline material realizes a density of at least 97% of its theoretical density. In yet another embodiment, a substantially single-phase polycrystalline material realizes a density of at least 97.5% of its theoretical density. In another embodiment, a substantially single-phase polycrystalline material realizes a density of at least 98% of its theoretical density. In yet another embodiment, a substantially single-phase polycrystalline material realizes a density of at least 98.2% of its theoretical density. In another embodiment, a substantially single-phase polycrystalline material realizes a density of at least 98.4% of its theoretical density. In yet another embodiment, a substantially single-phase polycrystalline material realizes a density of at least 98.6% of its theoretical density. In another embodiment, a substantially single-phase polycrystalline material realizes a density of at least 98.7% of its theoretical density. In yet another embodiment, a substantially single-phase polycrystalline material realizes a density of at least 98.8% of its theoretical density. In another embodiment, a substantially single-phase polycrystalline material realizes a density of at least 98.9% of its theoretical density. In yet another embodiment, a substantially single-phase polycrystalline material realizes a density of at least 99.0% of its theoretical density. In another embodiment, a substantially single-phase polycrystalline material realizes a density of at least 99.1% of its theoretical density. In yet another embodiment, a substantially single-phase polycrystalline material realizes a density of at least 99.2% of its theoretical density. In another embodiment, a substantially single-phase polycrystalline material realizes a density of at least 99.3% of its theoretical density. In yet another embodiment, a substantially single-phase polycrystalline material realizes a density of at least 99.4% of its theoretical density. In another embodiment, a substantially single-phase polycrystalline material realizes a density of at least 99.5% of its theoretical density. In yet another embodiment, a substantially single-phase polycrystalline material realizes a density of at least 99.6% of its theoretical density. In another embodiment, a substantially single-phase polycrystalline material realizes a density of at least 99.7% of its theoretical density. In yet another embodiment, a substantially single-phase polycrystalline material realizes a density of at least 99.8% of its theoretical density. In another embodiment, a substantially single-phase polycrystalline material realizes a density of at least 99.9% of its theoretical density.

In one embodiment, a new substantially single-phase polycrystalline material realizes at least equivalent plasma etch resistance as compared to a baseline material, wherein the baseline material is a single-phase polycrystalline material comprising 90 mol. % yttria and 10 mol. % zirconia and with less than 5 ppm of aluminum. In another embodiment, a substantially single-phase polycrystalline material realizes a plasma etch resistance that is at least 1% improved over the baseline material. In yet another embodiment, a substantially single-phase polycrystalline material realizes a plasma etch resistance that is at least 2% improved over the baseline material. In another embodiment, a substantially single-phase polycrystalline material realizes a plasma etch resistance that is at least 3% improved over the baseline material. In another embodiment, a substantially single-phase polycrystalline material realizes a plasma etch resistance that is at least 4% improved over the baseline material. In yet another embodiment, a substantially single-phase polycrystalline material realizes a plasma etch resistance that is at least 5% improved over the baseline material. In another embodiment, a substantially single-phase polycrystalline material realizes a plasma etch resistance that is at least 6% improved over the baseline material. In yet another embodiment, a substantially single-phase polycrystalline material realizes a plasma etch resistance that is at least 7% improved over the baseline material. In another embodiment, a substantially single-phase polycrystalline material realizes a plasma etch resistance that is at least 8% improved over the baseline material. In yet another embodiment, a substantially single-phase polycrystalline material realizes a plasma etch resistance that is at least 9% improved over the baseline material. In another embodiment, a substantially single-phase polycrystalline material realizes a plasma etch resistance that is at least 10% improved over the baseline material.

### iv. Product Form and Applications

The new substantially single-phase polycrystalline materials may take on a variety of product forms and may be used in a variety of industrial applications. In one embodiment, a new single-phase polycrystalline material is a bulk (monolithic) single-phase polycrystalline material. In one embodiment, a new polycrystalline material is used in a semiconductor processing application. In one embodiment, a new polycrystalline material is in the form of a semiconductor component. In one embodiment, the semiconductor component is configured for use in a plasma environment. In one embodiment, the semiconductor component is a plasma processing chamber component. In one embodiment, the semiconductor component is in the form of a nozzle blank or a nozzle. In one embodiment, the semiconductor component is a plasma processing chamber lid. In one embodiment, the semiconductor component is a plasma processing chamber gas distribution component (e.g., a gas distribution plate). In one embodiment, the semiconductor component is an electrostatic chuck component.

### v. Material Characterization

The below standards should be used to determine material properties of the substantially single-phase polycrystalline materials described herein.

As noted above, x-ray diffraction (XRD) may be used to determine the amount of crystalline phases of the polycrystalline materials described herein. The XRD instrument should be a Bruker D8 Discover (Bruker Corp., 40 Manning Rd, Billerica, MA 01821) or comparable XRD instrument. The XRD radiation should be copper K-alpha radiation. The power should be 1.6 kW. The scan range should be 20° to 70° (2 theta) (d=4.5A to 1.35A). The below table provides some primary and secondary peaks of crystalline phases for material characterization purposes. Primary and secondary peaks for other materials (e.g., ytterbium oxide) are known to those skilled in the art and may be determined using standard crystallographic techniques and reference materials.

| Phase | Primary Peak | Secondary Peak |
|---|---|---|
| Yttria (Y₂O₃) | [2 2 2] @ d = 3.061 Å | [4 4 0] @ d = 1.874 Å |
| | (measured at 3.054 Å) | (measured at 1.870 Å) |
| Zirconia (ZrO₂) [cubic] | [1 1 1] @ d = 2.964 Å | [220] @ d = 1.815 Å |
| Alumina (Al₂O₃) | [1 0 4] @ d = 2.551 Å | \|[1 1 6] @ d = 1.602 Å |
| | (measured at 2.552 Å) | (measured at 1.602 Å) |
| Yttrium aluminum | [1 2 2] @ d = 3.014 Å | [0 3 2] @ d = 2.915 Å |
| monoclinic | (measured at 3.019 Å) | (measured at 2.914 Å) |
| (YAM, Y₄Al₂O₉) | | |
| Yttrium zirconate | [1 1 1] @ d = 3.003 Å | [2 2 0] @ d = 1.839 Å |
| (YZ, Y₄Zr₃O₁₂) | (measured at d = 3.007 Å) | (measured at d = 1.841 Å) |

Grain size should be measured in accordance with ASTM E112-13(2021).

Plasma etch resistance should be measured in the presence of CF₄ gas at a flow rate of 50 SCCM under a pressure of 5 Pa (Pascals) at 135 Watts and 13.56 MHz RF power, with a 10 W bias.

### vi. Substitution of Other Rare Earth Elements for Yttrium

As explained previously, while the above disclosures generally describe substantially single-phase yttria-zirconia polycrystalline materials, one or more other rare earth (RE) elements may be partially or wholly substituted for yttrium while still achieving a substantially single-phase polycrystalline structure. Suitable other rare earth elements that may be partially or wholly substituted for yttrium include the those of the Lanthanide series of elements, i.e., lanthanum (Ln), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). Like yttrium, these other rare earth elements may be in the form of rare earth oxides (REO) in the substantially single-phase polycrystalline materials. For purposes of the present patent application, yttria is considered a rare earth oxide (REO). In one embodiment, the rare earth oxide is selected from the group consisting of yttrium oxide (yttria), ytterbium oxide, erbium oxide, or combinations thereof. In one embodiment, the rare earth oxide is or comprises ytterbium oxide. In one embodiment, the rare earth oxide is or comprises erbium oxide. In one embodiment, the rare earth oxides comprises both yttrium oxide and ytterbium oxide. In one embodiment, the rare earth oxides consists essentially of, or consist of, yttrium oxide and ytterbium oxide. In one embodiment, ytterbium is partially substituted for the yttrium. In another embodiment, ytterbium is wholly substituted for the yttrium.

In one embodiment, a powder suited for producing a substantially single-phase material may be characterized by the following equation:

$$1 - x \{ {[ {{Y}_{1 - Z} ( {M}_{1} + {M}_{2} + {M}_{3} + … )}_{Z} ]}_{2} {O}_{3} \} x {ZrO}_{2} \qquad ( 1 )$$

wherein:
M is any Lanthanide series element at any applicable molar ratio;
X is from 0.001 to 0.2;
Y is yttria; and
Z is from 0 to 1.0.
   The above equation is based on moles of the constituents. The above equation should be understood to allow for tolerable amounts of impurities that do not affect the basic and novel properties of the material. Non-limiting examples of suitable formulations include:
0.9 [(Y_{0.5} Yb_{0.5})₂ O₃ ]·0.1 ZrO₂, e.g., a powder comprising 90 mol. % of a 50/50 molar mixture of oxides of yttrium and ytterbium and 10 mol. % zirconia;
0.9 [(Y_{0.5} Yb_{0.3} Er_{0.2})₂ O₃ ]·0.1 ZrO₂, e.g., a powder comprising 90 mol. % of a 50/30/20 molar mixture of oxides of yttrium, ytterbium and erbium, respectively, and 10 mol. % zirconia;
0.8 (Er₂O₃)·0.2 ZrO₂, e.g., a powder comprising 80 mol. % erbium oxide and 20 mol. % zirconia);
0.8 (Yb₂O₃)·0.2 ZrO₂, e.g., a powder comprising 80 mol. % ytterbium oxide and 20 mol. % zirconia.

As noted above, in one embodiment, the rare earth oxides consists essentially of, or consist of, yttrium oxide and ytterbium oxide. In one embodiment, a total molar amount of the at least one rare earth oxide is REO_{Tot}, wherein REO_{Tot} consists essentially of A mol. % ytterbium oxide and B mol. % yttria oxide, wherein A is at least 1 mol. %, wherein B is at least 1 mol. %, and wherein A+B≥95 mol. % (i.e., mol. % ytterbium oxide plus mol. % yttrium oxide totals at least 95 mole percent). In one embodiment, A+B≥96 mol. %. In another embodiment, A+B≥97 mol. %. In yet another embodiment, A+B≥98 mol. %. In another embodiment, A+B≥98.5 mol. %. In yet another embodiment, A+B≥99 mol. %. In another embodiment, A+B≥99.5 mol. %. In yet another embodiment, A+B≥99.9 mol. %. In another embodiment, A+B≥99.99 mol. %. In one embodiment, A exceeds B (i.e., a material includes more ytterbium oxide as compared to yttrium oxide). In another embodiment, A is less than B (i.e., a material include less ytterbium oxide as compared to yttrium oxide). In one embodiment A≈B, i.e., a material includes substantially equimolar amounts of ytterbium oxide and yttrium oxide. In one embodiment, A is at least 5 mol. %. In another embodiment, A is at least 10 mol. %. In yet another embodiment, A is at least 20 mol. %. In another embodiment, A is at least 40 mol. %. In yet another embodiment, A is at least 50 mol. %. In another embodiment, A is at least 60 mol. %. In yet another embodiment, A is at least 75 mol. %. In another embodiment, A is at least 80 mol. %. In yet another embodiment, A is at least 85 mol. %. In another embodiment, A is at least 90 mol. %. In yet another embodiment, A is at least 95 mol. %. In another embodiment, A is at least 98 mol. %. In yet another embodiment, A is at least 99 mol. %. In one embodiment, A is from 10-99 mol. %. In another embodiment, A is from 40-60 mol. %. In yet another embodiment, A is from 50-95 mol. %.

In one embodiment, a powder suited for producing a substantially single-phase material may be characterized by the following equation:

$$1 - x \{ {[ {Y}_{1 - Q} {Yb}_{Q} ]}_{2} {O}_{3} \} x {ZrO}_{2} \qquad ( 2 )$$

wherein:
X is from 0.001 to 0.2;
Y is yttria;
Yb is ytterbium; and
Q is from 0.01 to 0.99.
   The above equation is based on moles of the constituents. The above equation should be understood to allow for tolerable amounts of impurities that do not affect the basic and novel properties of the material.

As shown above, the value of Q may be from 0.01 to 0.99 or any numerical hundredth value therebetween (i.e., 0.02, 0.03, etc. . . . 0.97, 0.98). In one embodiment, Q is at least 0.1 (≥10 mol. % ytterbia; ≤90% mol. % yttria). In another embodiment, Q is at least 0.2 (≥20 mol. % ytterbia; ≤80% mol. % yttria). In yet another embodiment, Q is at least 0.4 (≥40 mol. % ytterbia; ≤60% mol. % yttria). In another embodiment, Q is at least 0.5 (≥50 mol. % ytterbia; ≤50% mol. % yttria). In yet another embodiment, Q is at least 0.6 (≥60 mol. % ytterbia; ≤40% mol. % yttria). In another embodiment, Q is at least 0.75 (≥75 mol. % ytterbia; ≤25% mol. % yttria). In yet another embodiment, Q is at least 0.8 (≥80 mol. % ytterbia; ≤20% mol. % yttria). In another embodiment, Q is at least 0.85 (≥85 mol. % ytterbia; ≤15% mol. % yttria). In yet another embodiment, Q is at least 0.9 (≥90 mol. % ytterbia; ≤10% mol. % yttria). In another embodiment, Q is at least 0.95 (≥95 mol. % ytterbia; ≤5% mol. % yttria). In yet another embodiment, Q is at least 0.98 (≥98 mol. % ytterbia; ≤2% mol. % yttria). In another embodiment, Q is 0.99 (99 mol. % ytterbia; 1% mol. % yttria). In one approach, Q is from 0.1 to 0.99 (10-99 mol. % ytterbia; 90-1% mol. % yttria). In another approach, Q is from 0.4 to 0.6 (40-60 mol. % ytterbia; 60-40% mol. % yttria). In another approach, Q is from 0.5 to 0.95 (50-95 mol. % ytterbia; 50-5% mol. % yttria). In one embodiment, Q is about 0.5, i.e., ytterbia and yttria are substantially equimolar.

Like the substantially single-phase yttria-zirconia polycrystalline materials, the substantially single-phase REO-zirconia polycrystalline materials may additionally include from 40 to 7000 ppm aluminum, as described in Section (i), above. The aluminum may enter the solid solution phase or it may react with the yttrium or the Lanthanide series elements to form a detectable amount of secondary phase, for example, YAM (Y₄Al₂O₉) or YbAM (Yb₄Al₂O₉). Accordingly, all of the disclosures of Sections (i)-(v), above, pertaining to substantially single-phase polycrystalline materials of yttria-zirconia, apply equally to this Section (vi), including the disclosures surrounding suitable amounts of solid solution phase (≥95%), suitable zirconia compositions, suitable yttria compositions (for which other RE elements may be wholly or partially substituted), suitable aluminum compositions, suitable average grain sizes, suitable standard deviation pertaining to average grain sizes, suitable maximum grain sizes, suitable methods of manufacture, suitable properties (e.g., density), suitable product forms, and suitable material characterization methods.

### vii. Miscellaneous

These and other aspects, advantages, and novel features of this new technology are set forth in part in the descriptions and figures herein and will become apparent to those skilled in the art upon examination of the descriptions and figures herein, or may be learned by practicing one or more embodiments of the technology provided for by the present disclosure.

Among those benefits and improvements that have been disclosed, other objects and advantages of this invention will become apparent from the descriptions and figures herein. Detailed embodiments of the present invention are disclosed herein; however, it is to be understood that the disclosed embodiments are merely illustrative of the invention that may be embodied in various forms. In addition, each of the examples given in connection with the various embodiments of the invention is intended to be illustrative, and not restrictive.

Throughout the specification and claims, the following terms take the meanings explicitly associated herein, unless the context clearly dictates otherwise. The phrases “in one embodiment” and “in some embodiments” as used herein do not necessarily refer to the same embodiment(s), though they may. Furthermore, the phrases “in another embodiment” and “in some other embodiments” as used herein do not necessarily refer to a different embodiment, although they may. Thus, various embodiments of the invention maybe readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references, unless the context clearly dictates otherwise. The meaning of “in” includes “in” and “on”, unless the context clearly dictates otherwise.

While a number of embodiments of the present invention have been described, it is understood that these embodiments are illustrative only, and not restrictive, and that many modifications may become apparent to those of ordinary skill in the art. Further still, unless the context clearly requires otherwise, the various steps may be carried out in any desired order, and any applicable steps may be added and/or eliminated.

### BRIEF DESCRIPTION OF THE DRAWINGS

FIG. 1 illustrates one non-limiting embodiment of a method for producing the new substantially single-phase polycrystalline materials described herein.

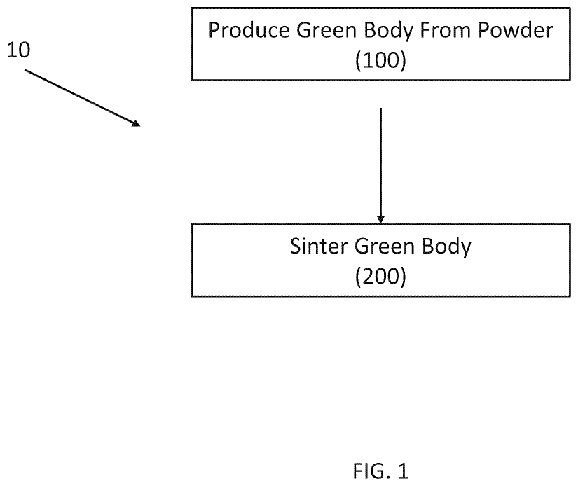

FIG. 2 is an XRD (x-ray diffraction) analysis of the Example 1 sintered sample, showing a single phase, Y₂O₃+ZrO₂ solid solution with no secondary phase identified at detection limits.

FIG. 3 is an XRD analysis of the Example 2 sintered sample (450 ppm of Al), showing a single phase, Y₂O₃+ZrO₂ solid solution with no secondary phase identified at detection limits.

FIG. 4 is an XRD of Sample No. 8 (5040 ppm of Al) of Example 3, showing approximately 3 wt. % YAM phase (yttria aluminum monoclinic) with the remainder being essentially the Y₂O₃+ZrO₂ solid solution phase.

FIG. 5a is an XRD of the Example 4 sintered sample, showing a single phase, Y₂O₃+ZrO₂ solid solution with no secondary phase identified at detection limits. (Note that the incorporation of 10 mole % ZrO₂ into the Y₂O₃ structure results in a contraction of the lattice parameter from 10.596 Å to 10.579 Å.)

FIG. 5b is a SEM image of a polished, thermally etched surface of the Example 4 material at a magnification of 10,000×.

### DETAILED DESCRIPTION

### Example 1—Production of Yttria-Zirconia Materials

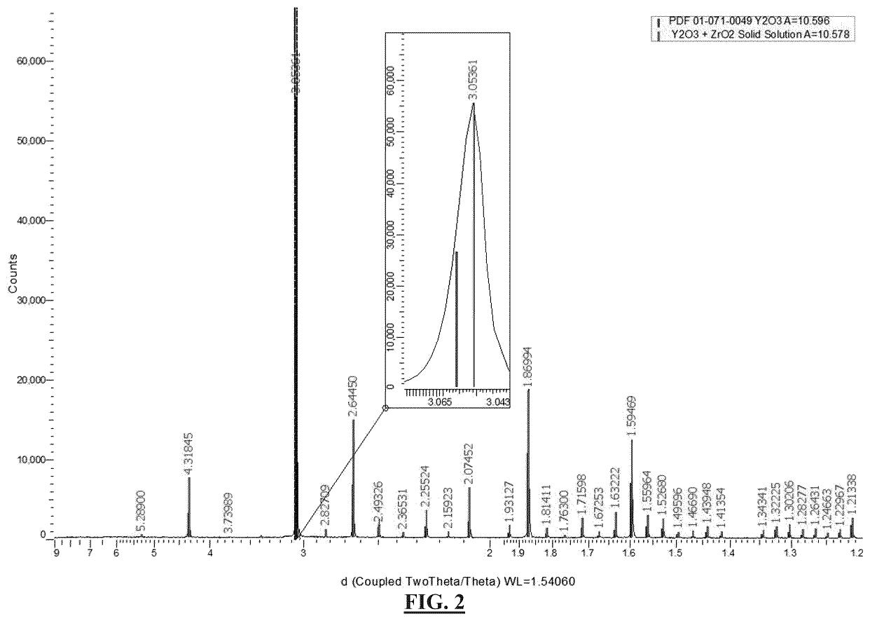

A powder comprising 90 mol. % yttria (Y₂O₃) and 10 mol. % zirconia (ZrO₂) was formulated using reverse osmosis water and milled to an appropriate particle size. The powder was then mixed with an organic binder to produce a slip, after which the slip was spray dried to produce a final powder. Test samples from the final powder were prepared by pressing at 15 kpsi, followed by pressureless (ambient pressure) sintering in air at 1600° C. for 6 hours or at 1680° C. for 6 hours. An X-ray diffraction (XRD) analysis (FIG. 2) showed that the sample materials were entirely single-phase, i.e., the materials consisted of a 100% solid solution structure of yttria-zirconia. The sintered test samples realized densities of ≤4.5 g/cm³ and 4.92 g/cm³, respectively. Given that the theoretical density of a 90:10 Y₂O₃:ZrO₂ (molar ratio) material is approximately 5.08 g/cm³ (assuming direct substitution of zirconium for yttrium ions on the yttria lattice), the first test sample was considered to have an extremely poor density (less than 88.5% of theoretical. The density of the second test sample was 96.9% but required a much higher firing temperature and still did not realize a density in excess of 98% of theoretical.

### Example 2—Production of Yttria-Zirconia Materials with Aluminum Doping

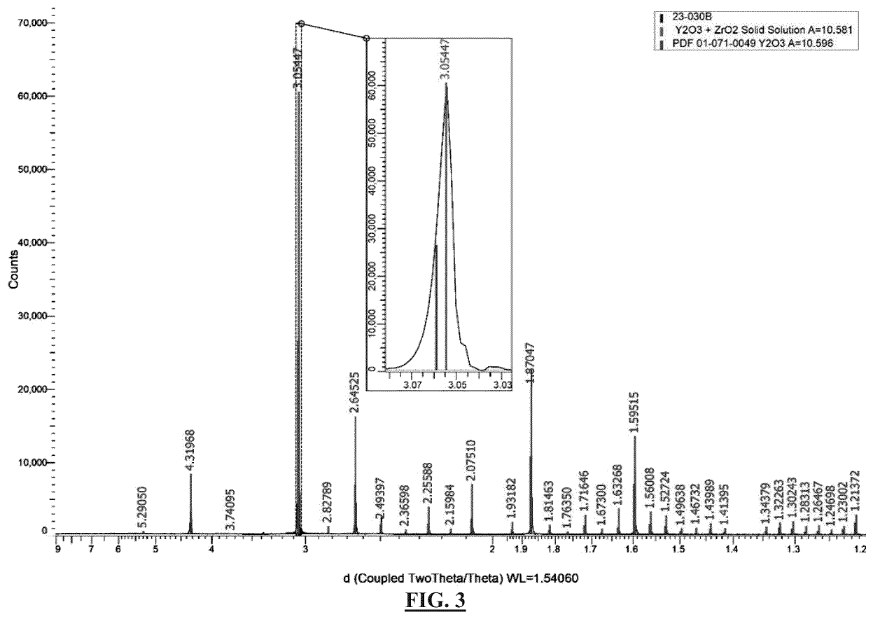

A powder comprising 90 mol. % yttria (Y₂O₃) and 10 mol. % zirconia (ZrO₂) was formulated as per Example 1, except 900 ppm (by weight) of boehmite (AlOOH) was added to the slip and dispersed, after which the slip was spray dried to produce a final powder. Test samples from the final powder were then prepared by pressing at 15 kpsi, followed by pressureless sintering in air at 1600° C. for 6 hours or at 1680° C. for 6 hours. Here, the test samples unexpectedly realized densities of 5.03 g/cm³ and 5.04 g/cm³, respectively, i.e., densities in excess of 99% of the theoretical density. Again, an XRD analysis (FIG. 3) showed the sample was entirely comprised of a yttria-zirconia solid solution structure, indicating the aluminum was present in solid solution or in one or more phases below the detection limit of XRD.

### Example 3—Yttria-Zirconia Materials with Various Aluminum Doping Levels

A powder comprising 90 mol. 0% yttria (Y₂O₃) and 10 mol. % zirconia (ZrO₂) was formulated as per Example 1. Except for a control sample (Sample No. 1), various amounts of boehmite were added and dispersed to produce distinct slips. These slips were then dried to produced various final powders. Test samples from the final powders were then prepared by pressing at 15 kpsi, followed by pressureless sintering in air at 1600° C. for 6 hours. Table 1, below, shows the amount of boehmite added per sample, as well as the amount of aluminum in the final compositions and the density results.

TABLE 1
Example 3 Compositions and Densities

| | Amount of Boehmite | Aluminum content | | Percent of |
|---|---|---|---|---|
| Sample | (AlOOH) added to slip | (ppm, by weight - | Fired Density | Theoretical |
| No. | (wt. %) | calculated) | (g/cm³)* | Density |
| 1 | 0 | 0 | 4.522 | 89.0 |
| 2 | 0.01 | 45 | 4.572 | 90.0 |
| 3 | 0.02 | 90 | 4.623 | 91.0 |
| 4 | 0.05 | 225 | 4.745 | 93.4 |
| 5 | 0.09 | 405 | 5.027 | 99.0 |
| 6 | 0.18 | 810 | 5.062 | 99.6 |
| 7 | 0.45 | 2025 | 5.062 | 99.6 |
| 8 | 1.12 | 5040 | 5.049 | 99.4 |
| 9 | 4.55 | 20475 | 4.891 | 96.3 |
| 10 | 11.25 | 50625 | 4.786 | 94.2 |

*The reported fired densities are an average of three specimens.

Table 2, below, shows the calculated final amounts of yttria, zirconia, and alumina (assumes all aluminum from the boehmite is converted to alumina).

TABLE 2
Calculated amounts of yttria, zirconia,
and alumina in Example 3 samples

| Sample | Mol % (Calculated) | | | Weight % (Calculated) | | |
|---|---|---|---|---|---|---|
| No. | Y₂O₃ | ZrO₂ | Al₂O₃ | Y₂O₃ | ZrO₂ | Al₂O₃ |
| 1 | 90 | 10 | 0 | 94.284 | 5.716 | 0 |
| 2 | 89.984 | 9.998 | 0.018 | 94.276 | 5.716 | 0.009 |
| 3 | 89.968 | 9.996 | 0.036 | 94.268 | 5.715 | 0.017 |
| 4 | 89.919 | 9.991 | 0.090 | 94.244 | 5.714 | 0.043 |
| 5 | 89.855 | 9.984 | 0.162 | 94.212 | 5.712 | 0.077 |
| 6 | 89.709 | 9.968 | 0.323 | 94.140 | 5.708 | 0.153 |
| 7 | 89.275 | 9.920 | 0.806 | 93.924 | 5.695 | 0.383 |
| 8 | 88.207 | 9.801 | 1.992 | 93.394 | 5.662 | 0.952 |
| 9 | 82.983 | 9.217 | 7.830 | 90.772 | 5.503 | 3.869 |
| 10 | 73.676 | 8.186 | 18.138 | 86.052 | 5.217 | 9.565 |

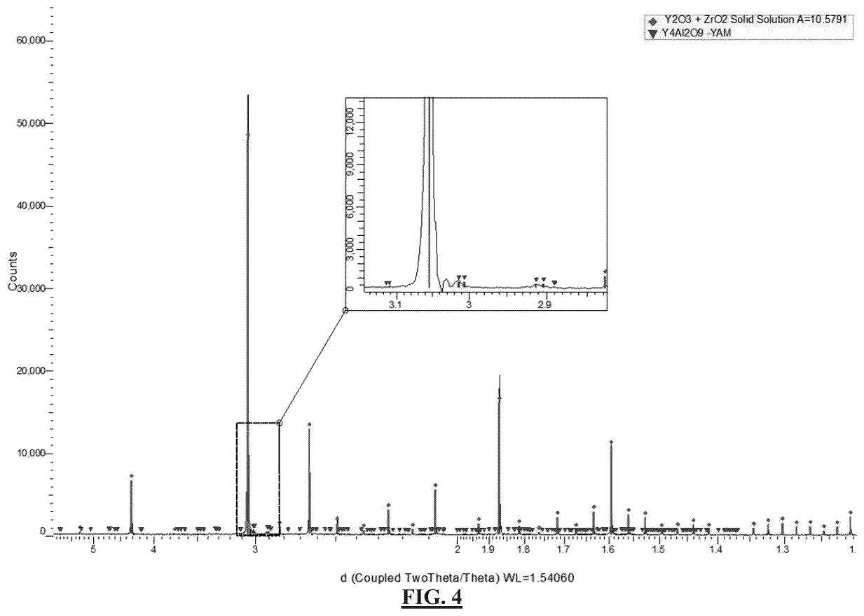

XRD analyses of Sample Nos. 4, 6, and 8 were also completed. Like Examples 1-2, the XRD analyses of Samples 4 and 6 showed that those samples were entirely comprised of a yttria-zirconia solid solution structure, indicating the aluminum was present in solid solution or in one or more phases below the detection limit of XRD. However, the XRD analysis of Sample 8 (FIG. 4) showed that the sample contained about 3 wt. % yttrium aluminum monoclinic phase (YAM, Y₄Al₂O₉), the remainder being yttria-zirconia solid solution phase.

As for density, as expected, Sample No. 1 with no aluminum addition realized a very poor density of only 89.0% of theoretical. Conversely, the samples with aluminum additions realized significantly improved densities. Even as little as about 40 ppm aluminum (by weight) may impact the density of the substantially single-phase yttria-zirconia polycrystalline materials, with extremely high densities being realized with about 400-5000 ppm aluminum. Additions of aluminum beyond about 20,000 ppm degrade density. However, as indicated by the XRD analysis of Sample No. 8, it is anticipated that additions of aluminum beyond 7000 ppm may not realize the desired substantially single-phase polycrystalline material (e.g., by having more than 5 wt. % YAM phase (Y₄Al₂O₉), for instance). It is anticipated that an XRD analysis of Samples 9-10 will show that that those samples do not realize a substantially single-phase polycrystalline structure because those samples do not have at least 95 wt. % of the yttria-zirconia solid solution phase. It is therefore anticipated that aluminum doping of 40-7000 ppm (by weight) may be useful in fabricating commercially viable products. Aluminum doping at 100-6000 ppm, or 200-5000 ppm, or 300-4000 ppm, or 400-3000 ppm, or 450-2000 ppm, or 500-1500 ppm (by weight) may be particularly beneficial. Reduced sintering temperatures and/or pressureless sintering in air may be used to produce the extremely dense single-phase yttria-zirconia materials. Low production costs may therefore be realized.

### Example 4—Yttria-Zirconia Materials Doped Via Aluminum Nitrate Solution

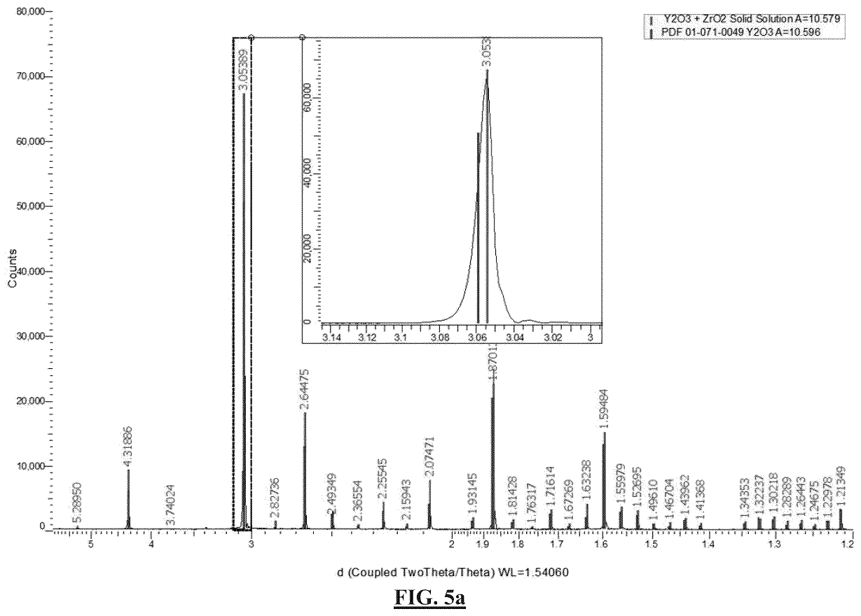

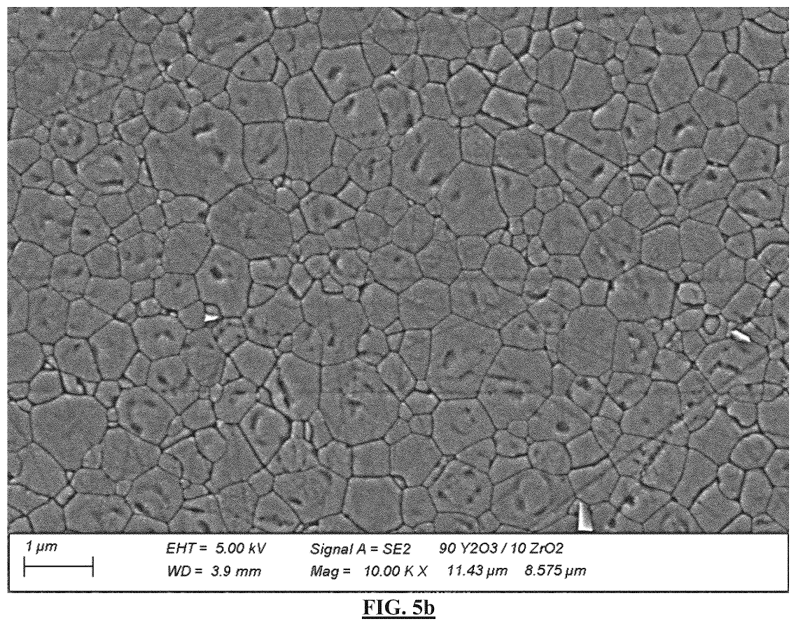

A powder comprising 90 mol. % yttria (Y₂O₃) and 10 mol. % zirconia (ZrO₂) was formulated as per Example 1. The powder was exposed to an aqueous solution of aluminum nitrate nonahydrate (Al(NO₃)₃·9H₂O) to provide 650 ppm of aluminum doping. The powder was then mixed with an organic binder to produce a slip, after which the slip was spray dried to produce a final powder. Test samples from the final powder were prepared by pressing at 15 kpsi, followed by pressureless (ambient pressure) sintering in air at 1600° C. for 6 hours. An XRD analysis (FIG. 5a) showed the sample was entirely comprised of a yttria-zirconia solid solution structure, indicating the aluminum was present in solid solution or in one or more phases below the detection limit of XRD. An SEM image of the sample was obtained (FIG. 5b), showing the sample achieved a fine, uniform grain structure. When measured in accordance with ASTM E112-13 at a magnification of 10,000×, the sample achieved an average grain size of 0.42 micrometers with a standard deviation of 0.07 micrometers and a maximum grain size of 1.63 micrometers. In other words, the standard deviation is only 16.7% of the average grain size and the maximum grain size is only 3.88 times larger the average grain size.

While the powders of Examples 1-4 were formulated to contain 90 mol. % yttria and 10 mol. % zirconia, it is anticipated that aluminum doping may benefit the density of various yttria-zirconia single-phase materials. For instance, it is anticipated that such powders may include 0.01 to 20 mol. % zirconia, the balance being essentially yttria. Aluminum in an amount of from 40 to 7000 ppm may also be added to those powders.

While the aluminum doping described in Examples 2-3 was via application of boehmite to the initial yttria-zirconia powders, and while the aluminum doping described in Example 4 was via exposure of the yttria-zirconia powder to an aluminum nitrate nonahydrate (Al(NO₃)₃·9H₂O) solution, it is anticipated that aluminum could be incorporated into the yttria-zirconia system in a variety of ways, including, for instance: (a) contacting the yttria-zirconia powders with other aqueous solutions comprising aluminum ions, (b) exposing the yttria-zirconia powders to reactive forms of aluminum other than boehmite, (c) milling of the yttria-zirconia powders with aluminum-containing media (e.g., attrition milling with alpha-alumina), and/or (d) use of yttria and/or zirconia powders that have been pre-doped with aluminum (e.g., doped with small amounts of alumina).

### Example 5—Testing of Additional REO Materials

Three different sample materials having the compositions listed in Table 3, below, were formulated as per Example 1. No aluminum was added to the first sample (5-1), whereas the second and third samples (5-2 and 5-3) were exposed to an aqueous solution of aluminum nitrate nonahydrate (Al(NO₃)₃·9H₂O) to provide 400 ppm of aluminum doping. The powders were then mixed with an organic binder to produce a slip, after which the slips were pan dried at 100° C. to produce the final powders.

TABLE 3
Compositions of Example 5 Materials

| | Yb₂O₃ | | Y₂O₃ | | ZrO₂ | | Aluminum |
|---|---|---|---|---|---|---|---|
| Sample | mol % | wt % | mol % | wt % | mol % | wt % | ppm |
| 5-1 | 90% | 96.6% | 0% | 0% | 10% | 3.36% | 0 |
| 5-2 | 90% | 96.6% | 0% | 0% | 10% | 3.36% | 400 |
| 5-2 | 45% | 60.88% | 45% | 34.89% | 10% | 4.23% | 400 |

Test samples from the final powders were prepared by pressing at 15 kpsi, followed by pressureless (ambient pressure) sintering in air at 1560° C. for 6 hours or at 1640° C. for 6 hours. An X-ray diffraction (XRD) analysis showed that the sample materials were entirely single-phase, i.e., the materials consisted of a 100% solid solution structure of ytterbia-zirconia (Samples 5-1, 5-2) or ytterbia-yttria-zirconia (Sample 5-3). Next, density and grain size measurements were taken, the results of which are shown in Table 4, below.

TABLE 4
Properties of Example 5 Materials

| | | | | | | Sample 5-3 | |
|---|---|---|---|---|---|---|---|
| | | Sample 5-1 | | Sample 5-2 | | (Doped | |
| | | (Undoped | | (Doped | | Yb₂O₃ + Y₂O₃ + | |
| Property | | Yb₂O₃ + ZrO₂) | | Yb₂O₃ + ZrO₂) | | ZrO₂) | |
| Theoretical | (g/cc) | 9.01 | | 9.01 | | 7.02 | |
| Density | | | | | | | |
| Sintering | (° C.) | 1560 | 1640 | 1560 | 1640 | 1560 | 1640 |
| Temperature | | | | | | | |
| Density | g/cc | 7.465 | 7.844 | 8.974 | 8.981 | 6.919 | 6.942 |
| | % | 82.85% | 87.06% | 99.60% | 99.68% | 98.56% | 98.89% |
| Grain Size | Avg | N/A | 0.51 | 0.68 | 1.54 | 0.72 | 1.48 |
| (μm) | Max | N/A | 1.3 | 2.852 | 6.3 | 3.171 | 4.7 |

As shown, just like the yttria-zirconia samples of Examples 1-4, the undoped ytterbia-zirconia sample realized poor density whereas the aluminum doped ytterbia-zirconia and ytterbia-yttria-zirconia samples realized very high densities. The aluminum doped samples were also able to achieve the ultra-high densities at low sintering temperatures. The aluminum doped samples also realized very fine grain sizes and with a low maximum grain size.

While various embodiments of the present disclosure have been described in detail, it is apparent that modifications and adaptations of those embodiments will occur to those skilled in the art. However, it is to be expressly understood that such modifications and adaptations are within the spirit and scope of the present disclosure.

What is claimed is:

1. A substantially single-phase polycrystalline material comprising yttria (Y₂O₃) and zirconia (ZrO₂), wherein the substantially single-phase polycrystalline material comprises from 0.01-20 mol. % zirconia and at least 80 mol. % yttria, and wherein the substantially single-phase polycrystalline material further comprises from 40 to 7000 ppm aluminum by weight, wherein the substantially single-phase polycrystalline material comprises at least 95 wt. % of a solid-solution of yttria-zirconia as measured by x-ray diffraction.

2. The substantially single-phase polycrystalline material of claim 1, comprising from 100 to 6000 ppm of the aluminum by weight.

3. The substantially single-phase polycrystalline material of claim 1, wherein the substantially single-phase polycrystalline material realizes a density of at least 95% of its theoretical density.

4. The substantially single-phase polycrystalline material of claim 1, comprising from 0.05 to 19.5 mol. % zirconia.

5. The substantially single-phase polycrystalline material of claim 1, comprising at least 95 mol. % yttria.

6. The substantially single-phase polycrystalline material of claim 1, wherein the substantially single-phase polycrystalline material comprises at least 96 wt. % of a solid-solution of yttria-zirconia.

7. The substantially single-phase polycrystalline material of claim 1, wherein the substantially single-phase polycrystalline material realizes an average grain size of not greater than 7 micrometers.

8. The substantially single-phase polycrystalline material of claim 7, wherein a standard deviation of the grain size is not greater than twice the average grain size.

9. The substantially single-phase polycrystalline material of claim 7, wherein the substantially single-phase polycrystalline material realizes a maximum grain size, and wherein the maximum grain size is not more than 20 times larger than the average grain size.

10. The substantially single-phase polycrystalline material of claim 1, wherein the substantially single-phase polycrystalline materials realizes at least equivalent plasma etch resistance as compared to a baseline material, wherein the baseline material is a single-phase polycrystalline material comprising 90 mol. % yttria and 10 mol. % zirconia and with less than 5 ppm of aluminum.

11. A method comprising:
(a) pressing a powder into a shaped component, wherein the powder comprises (i) 0.01-20 mol. % zirconia, (ii) at least 80 mol. % yttria, and (iii) from 40 to 7000 ppm of aluminum;
(b) sintering the shaped component at a sintering temperature of from 1200-1800° C., thereby forming a sintered component, wherein the sintered component is polycrystalline, wherein the sintered component is substantially single-phase realizing at least 95 wt. % of a solid-solution of yttria-zirconia as measured by x-ray diffraction, and wherein the sintered component realizes a density of at least 95% of theoretical.

12. The method of claim 11, comprising, prior to the pressing step, formulating the powder and wherein the formulating step comprises blending a yttria powder and a zirconia powder, thereby producing a powder blend.

13. The method of claim 12, wherein the formulating step comprising contacting the powder blend with a liquid phase material comprising aluminum and wherein the liquid phase material is an aqueous aluminum-containing solution.

14. The method of claim 12, wherein the formulating comprises contacting the powder blend with a solid phase material comprising aluminum and wherein the solid phase material comprises aluminum-containing milling media, and wherein the formulating step comprises milling the powder blend with the aluminum-containing milling media, thereby effecting mass transfer of at least some aluminum to the powder blend.

15. The method of claim 14, wherein the aluminum-containing milling media comprises alpha alumina.

16. The method of claim 11, wherein the shaped component is monolithic.

17. A substantially single-phase polycrystalline material comprising 0.1 to 20 mol. % zirconia (ZrO₂) and at least 80 wt. % of at least one rare earth oxide (REO), wherein the at least one rare earth oxide is selected from the group consisting of yttria, oxides of the Lanthanide series of elements, or combinations thereof, wherein the substantially single-phase polycrystalline material further comprises from 40 to 7000 ppm aluminum by weight, wherein the substantially single-phase polycrystalline material comprises at least 95 wt. % of a solid-solution of REO-zirconia as measured by x-ray diffraction.

18. A method comprising:
(a) pressing a powder into a shaped component, wherein the powder comprises (i) 0.01-20 mol. % zirconia, (ii) at least 80 wt. % of at least one rare earth oxide (REO), wherein the at least one rare earth oxide is selected from the group consisting of yttria, oxides of the Lanthanide series of elements, or combinations thereof, and (iii) from 40 to 7000 ppm of aluminum;
(b) sintering the shaped component at a sintering temperature of from 1200-1800° C., thereby forming a sintered component, wherein the sintered component is polycrystalline, wherein the sintered component is substantially single-phase realizing at least 95 wt. % of a solid-solution of REO-zirconia as measured by x-ray diffraction, and wherein the sintered component realizes a density of at least 95% of theoretical, wherein the rare earth oxide comprises at least one of ytterbium oxide, erbium oxide, and ytterbium oxide.
